(19) United States
(12) Patent Application Publication
(10) Pub. No.: US 2007/0097645 A1
(43) Pub. Date: May 3, 2007

(54) Heat pipe with expanded heat receiving section and heat dissipation module

(76) Inventors: Chao-yi Chen, Taipei City (TW); Wei Chung Hsiao, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/328,189

(22) Filed: Jan. 10, 2006

(30) Foreign Application Priority Data
Oct. 28, 2005 (TW) 94137974

(51) Int. Cl. H05K 7/20

(52) U.S. Cl. 361/700

(57) ABSTRACT

Disclosed is a heat pipe with expanded heat receiving section, and a heat dissipation module using the heat pipe. The heat-receiving section is in physical engagement with a heat conduction box of the heat dissipation module. A fan is arranged between the heat conduction box and a heat dissipation fin module. The heat conduction box and the heat dissipation fin module form, at locations corresponding to the heat-receiving section and the heat-dissipating section, a heat-receiving section receiving slot and a heat-dissipating section receiving slot, respectively, to receive and retain the heat-receiving section and the heat-dissipating section therein.

### FIELD OF THE INVENTION

The present invention relates to a heat pipe, and in particular to a heat pipe having a heat receiving section comprised of expanded tube to provide an enlarged area for thermal transfer, and a heat dissipation module using the heat-receiving-section-expanded heat pipe.

### BACKGROUND OF THE INVENTION

Integrated circuit devices have been widely used in a variety of industrial facility, measuring equipments, and computers. The integrated circuit devices must be maintained within specific working temperatures in order to function normally. Thus, the integrated circuit devices are often coupled to heat dissipation devices or systems to effectively dissipate heat to the surroundings for maintaining the specific working temperatures. This is particularly true for a central processing unit, which serves as an operation center of a computer system and thus the requirement for heat dissipation is even more severe.

With the increased speed of the central processing unit, and other integrated circuit devices, the performance of the heat dissipation or system has to be improved accordingly. The conventionally used heat dissipation board and heat dissipation fin are no longer capable to effectively cool the integrated circuit down to the specific working temperature. Thus, heat dissipation fans and heat pipes are additionally include in the heat dissipation system to enhance the heat removal rate and realizes effective heat dissipation. Further, since a notebook computer or a tablet computer is often of a smaller size and lighter weight, as compared to the regular desktop computer, the heat dissipation for the central processing unit of the notebook computer or tablet computer is subject to very severe requirement in performance. However, due to the smaller size, internal space of the notebook computer and the tablet computer is very limited, which imposes constraint to the design and installation of heat dissipation system in the notebook computer or the tablet computer.

FIG. 1 of the attached drawings shows a conventional heat-pipe-included heat dissipation module for a notebook computer. As shown in FIG. 1, the conventional heat dissipation module, which is generally designated with reference numeral 1, is positioned on and maintained in physical contact with a top face of a heat-generating element 2, such as a central processing unit. The heat dissipation module 1 comprises a heat conduction box 11, a fan 12, a heat dissipation fin module 13, a heat dissipation channel 14, and a heat pipe 15.

The heat dissipation module 1 is constructed so as to fix the fan 12 between the heat conduction box 11 and the heat dissipation fin module 13 and the heat dissipation fin module 13 is received and retained in the heat dissipation channel 14 that extends from the heat conduction box 11 and defines a plurality of air passages therein through which heat dissipation airflows caused by the fan 12 pass. The heat generated by the heat-generating element 2 can be effectively dissipated by the airflows generated by the fan 12, together with heat exchange effected by the heat dissipation fin module 13.

Also referring to FIG. 2 of the attached drawings, the heat pipe 15 of the heat dissipation module 1 is comprised of a heat-receiving section 151, a heat-transfer section 152, and a heat-dissipating section 153. The heat-receiving section 151 is connected to an end of the heat conduction box 11 of the heat dissipation module 1 that is in physical contact with the heat-generating element 2 and the heat dissipating section 153 is coupled to the heat dissipation fin module 13, whereby heat generated by the heat-generating element 2 is transferred through the heat-transfer section 152 and the heat-dissipating section 153 to the heat dissipation fins that comprise the heat dissipation fin module 13, which, together with the operation of the fan 12 that induces airflows for heat dissipation, may dissipate heat that is transferred to the heat dissipation fins to the surroundings.

A heat-receiving section receiving slot 16 and a heat-dissipating section receiving slot 17 are respectively formed in suitable locations on the heat conduction box 11 and the heat dissipation fin module 13. The heat-receiving section 151 and the heat-dissipating section 153 are respectively received and retained in the heat-receiving section receiving slot 16 and the heat-dissipating section receiving slot 17. This improves the heat transfer rate between the heat pipe 15 and the heat conduction box 11.

The conventional heat dissipation modules, although subject to severe constraint of limited inside space, can realize effect heat dissipation for notebook computers. In practical applications, although the heat pipe comprised of the conventional heat dissipation module plays a good role in heat transfer and the heat-receiving section of the heat pipe that is connected to the end of the heat dissipation module that is in physical contact with the heat-generating element does transfer heat from the connection therebetween, through the heat pipe, to the fin section, a portion of the heat is incorrectly transferred through the heat conduction box and inducing an undesired thermal build-up therein.

Adding one or more extra heat pipes or using a heat pipe of increased cross-section area has been proposed to overcome the poor performance of heat transfer in the conventional designs. These solutions, however, require additional occupation of the very limited space inside the notebook computers and are not, to some extents, economic.

Thus, the key challenge here is to improve the structure of the heat pipe itself, which allows for efficient transfer of heat from the heat-generating element to the heat dissipation fin module to effect excellent heat dissipation performance.

### SUMMARY OF THE INVENTION

An objective of the present invention is to provide a heat pipe having an expanded heat-receiving section, which effectively enhances the heat dissipation performance of a heat dissipation module that incorporates the heat pipe without addition of extra heat pipe(s).

Another objective of the present invention is to provide an improvement on the structure of heat pipe, which allows for further increasing contact area between the heat pipe and a heat source at positions of intense eat distribution identified by experiment and analysis of thermal and temperature distribution to further enhance performance of heat dissipation.

A further objective of the present invention is to provide a heat dissipation comprised of a heat pipe having an expanded heat-receiving section, whereby the performance of heat dissipation of the heat dissipation module is enhanced by the expanded heat-receiving section of the heat pipe in physical engagement with a heat conduction box of the heat dissipation module.

To realize the above objectives, in accordance with an embodiment of the present invention, a heat pipe comprises a heat-receiving section comprising an expanded tube of different geometry by which a contact area for heat transfer is increased to effectively enhance the performance of heat dissipation. In accordance with the present invention, the heat-receiving section of the heat pipe is extended to integrally form an expanded heat-receiving segment, which extends from an end of the heat-receiving section of the heat pipe and is in physical engagement with a heat conduction box of a heat dissipation module. A fan is further arranged between the heat conduction box of the heat dissipation module and a heat dissipation fin module.

In a preferred embodiment of the present invention, the heat conduction box and the heat dissipation fin module form, at positions corresponding to the heat-receiving section and a heat-dissipating section of the heat pipe, a heat-receiving section receiving slot and a heat-dissipating section receiving slot, respectively, for receiving and retaining therein the heat-receiving section and the heat-dissipating section of the heat pipe.

Compared to the conventional devices, the present invention enhances the heat dissipation performance of a heat dissipation module without adding extra heat pipe(s) and allows for further improvement of the heat dissipation performance by means of comparison and verification by experiments and analyses.

### BRIEF DESCRIPTION OF THE DRAWINGS

The present invention will be apparent to those skilled in the art by reading the following description of preferred embodiments thereof, with reference to the attached drawings, in which:

FIG. 1 is a perspective view showing a conventional heat dissipation module for a notebook computer;

FIG. 2 is an exploded view of the conventional heat dissipation module with a heat pipe detached from the module;

FIG. 3 is a perspective view of a heat dissipation module constructed in accordance with a first embodiment of the present invention;

FIG. 4 is an exploded view of the heat dissipation module of the present invention with a heat pipe detached therefrom;

FIG. 5 is a plan view of the heat pipe in accordance with the present invention;

FIG. 6 is a cross-sectional view taken along line 6-6 of FIG. 5;

FIG. 7 is a cross-sectional view taken along line 7-7 of FIG. 5;

FIG. 8 is a cross-sectional view taken along line 8-8 of FIG. 5;

FIG. 9 is an exploded view of a heat dissipation module constructed in accordance with a second embodiment of the present invention with a heat pipe detached from the module;

FIG. 10 is a perspective view of a heat dissipation module constructed in accordance with a third embodiment of the present invention;

FIG. 11 is an exploded view of the heat dissipation module of the third embodiment of the present invention with a heat pipe detached therefrom; and

FIG. 12 is an exploded view of a heat dissipation module constructed in accordance with a fourth embodiment of the present invention with a heat pipe detached from the module.

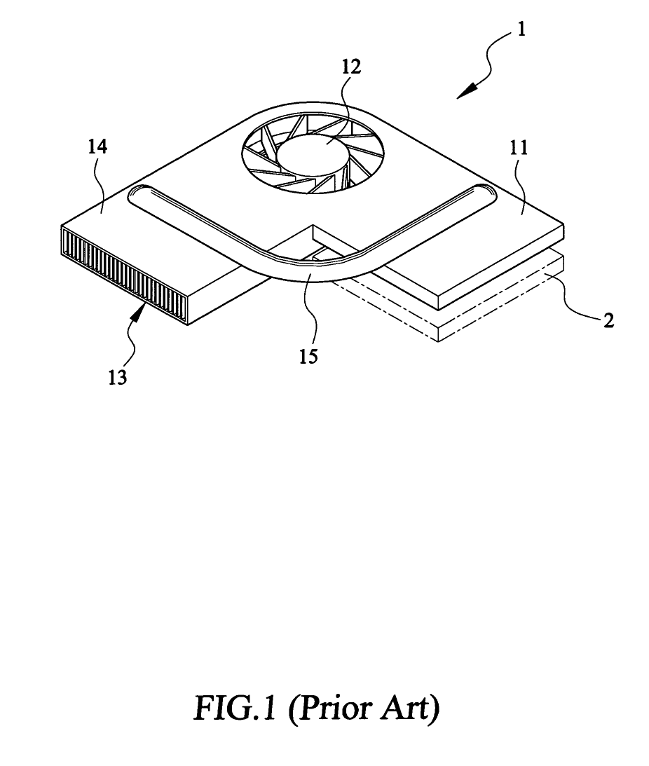

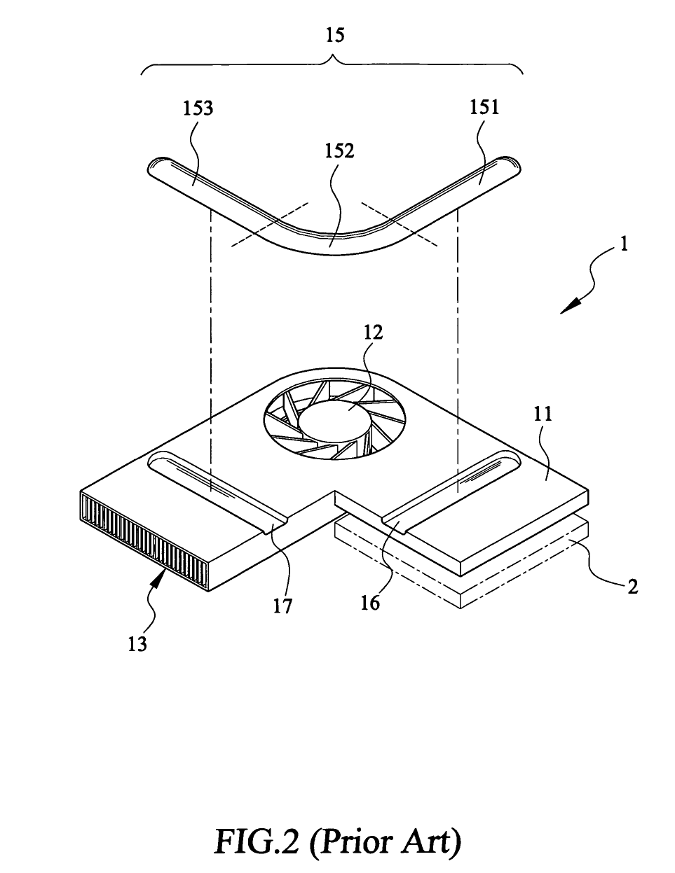

### DETAILED DESCRIPTION OF THE PREFERRED EMBODIMENTS

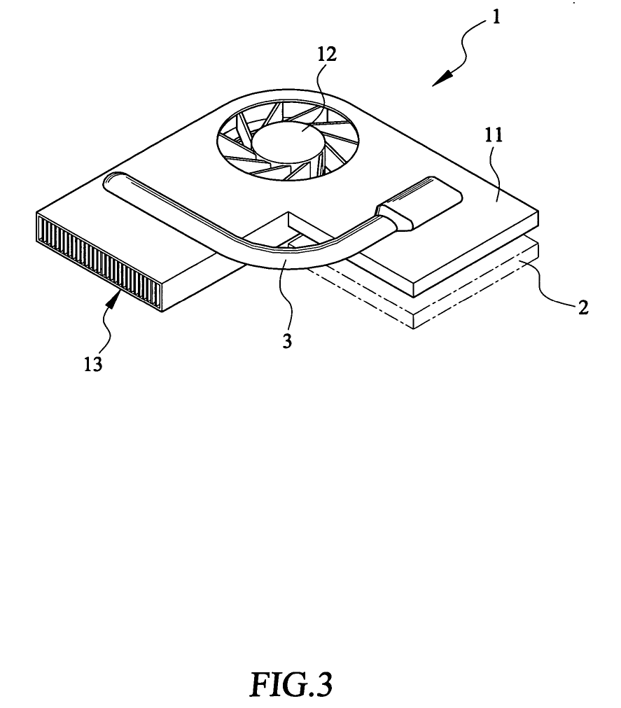

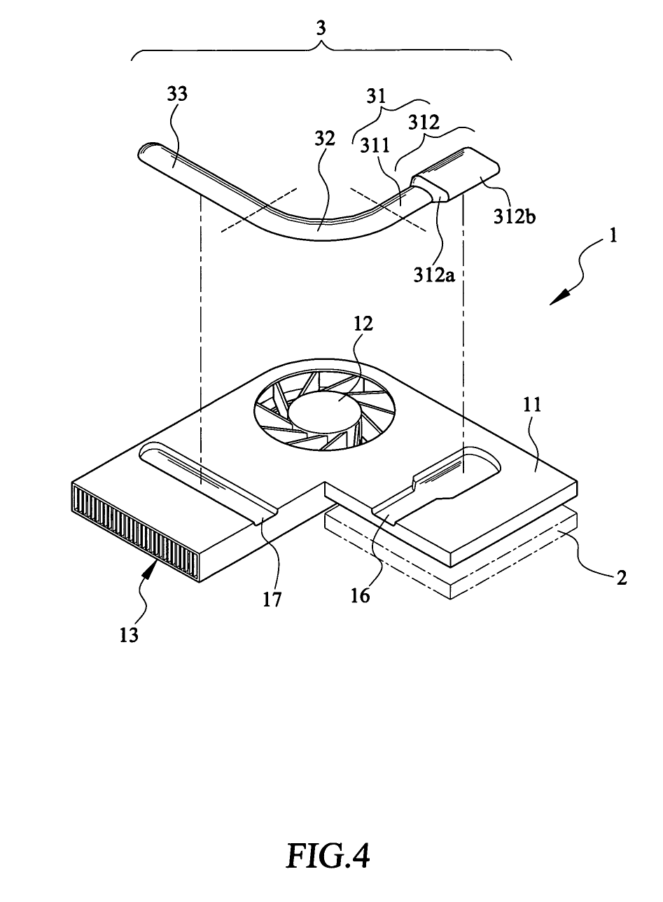

With reference to the drawings and in particular to FIGS. 3 and 4, which show a perspective view and an exploded view of a heat dissipation module constructed in accordance with a first embodiment of the present invention, generally designated with reference numeral 1, the heat dissipation module 1 of the first embodiment of the present invention comprises a uniformly-expanded heat pipe 3, which comprises a heat-receiving section 31, a heat-transfer section 32, and a heat-dissipating section 33.

The heat-receiving section 31 is coupled to an end of a heat conduction box 11 of the heat dissipation module 1 that physically contacts a heat source formed by a heat-generating element 2 and the heat-dissipating section 33 is coupled to a heat dissipation fin section 13 of the heat dissipation module 1 whereby heat generated by the heat-generating element 2 is transferred through the heat-transfer section 32 and the heat-dissipating section 33 to heat dissipation fins that constitute the heat dissipation fin module 13, which, together with heat dissipation airflows induced by a fan 12, effectively dissipates heat transferred to the heat dissipation fins to the surroundings.

A major difference between the instant embodiment and the conventional heat pipe is that the heat-receiving section 31 of the uniformly-expanded heat pipe 3 of the present invention comprises a primitive segment 311 and an expanded segment 312. An end of the primitive segment 311 is connected to the heat-transfer section 32. The expanded segment 312 has a gradually-expanded portion 312a and a uniformly-expanded portion 312b.

The gradually-expanded portion 312a has an end connected to an opposite end of the primitive segment 311 and the uniformly-expanded portion 312b extends from an opposite end of the gradually-expanded portion 312a. In the instant embodiment, the uniformly-expanded portion 312b has a cross-sectional dimension greater than a cross-sectional dimension of the primitive segment 311, while cross-sectional dimension of the gradually-expanded portion 312a is gradually increased from the connection thereof with the primitive segment 311 toward the connection thereof with the uniformly-expanded portion 312b.

The heat conduction box 11 and the heat dissipation fin module 13 form, at suitable locations, a heat-receiving section receiving slot 16 and a heat-dissipating section receiving slot 17. The heat-receiving section 31 and the heat-dissipating section 33 of the uniformly-expanded heat pipe 3 are received and retained in the heat-receiving section receiving slot 16 and the heat-dissipating section receiving slot 17 of the heat dissipation module 1, respectively.

In practice, the primitive segment 311, the gradually-expanded portion 312a, and the uniformly-expanded portion 312b are integrally formed together.

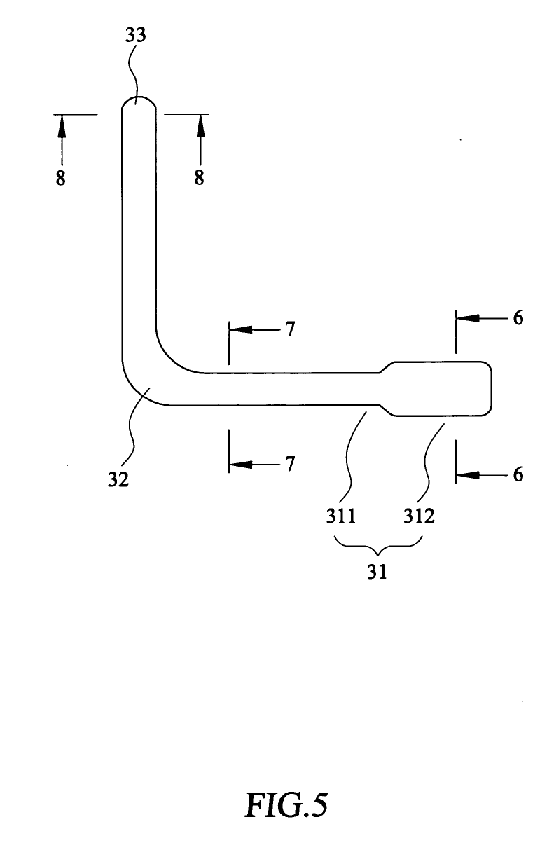

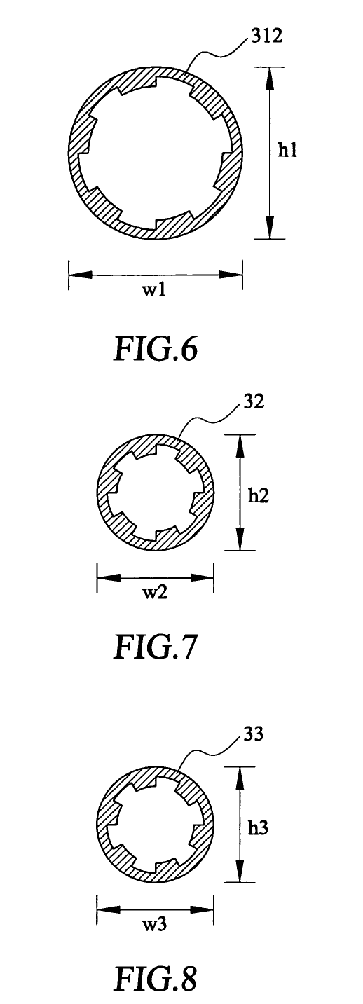

Also referring to FIGS. 5-8, which show a plan view of the heat pipe 3, and cross-sectional views taken along lines 6-6, 7-7, and 8-8 of FIG. 5, respectively, the dimensions of the heat-receiving section 31, the expanded segment 312, the heat-transfer section 32, and the heat-dissipating section 33 will be discussed.

By designating a first dimension (height) and a second dimension (width) of the expanded segment 312 of the heat-receiving section 31 with h1 and w1 respectively; a first dimension (height) and a second dimension (width) of the heat-transfer section 32 with h2 and w2 respectively; and a first dimension (height) and a second dimension (width) of the heat-dissipating section 33 with h3 and w3 respectively, the following conditions are satisfied:

(a) The first dimension h1 of the expanded segment 312 is greater than the first dimension h2 of the heat-transfer section 32;

(b) The first dimension h1 of the expanded segment 312 is greater than the first dimension h3 of the heat-dissipating section 33;

(c) The second dimension w1 of the expanded segment 312 is greater than the second dimension w2 of the heat-transfer section 32; and

(d) The second dimension w1 of the expanded segment 312 is greater than the second dimension w3 of the heat-dissipating section 33.

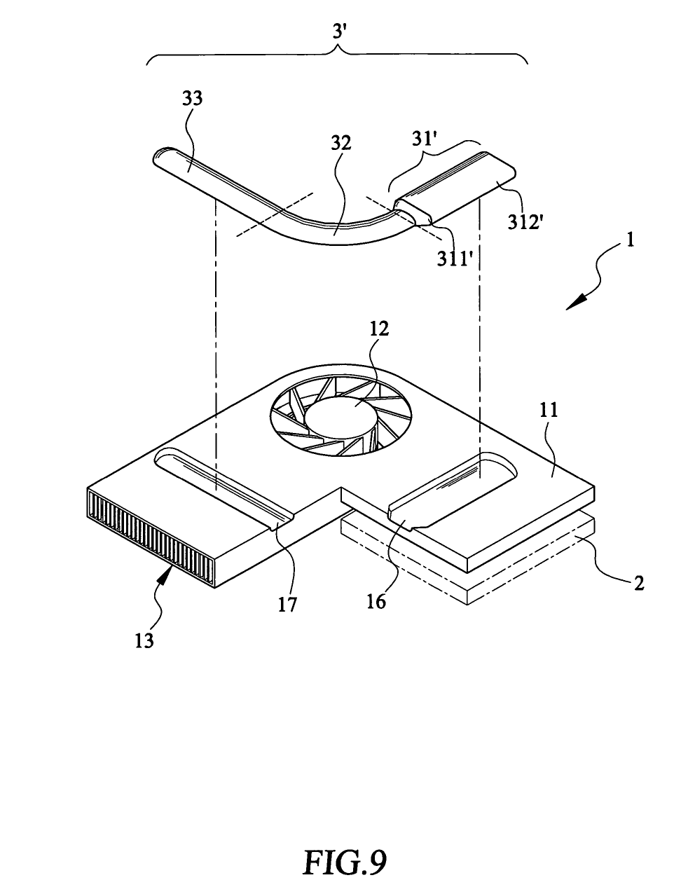

With reference to FIG. 9, which shows an exploded view of a heat dissipation module, also designated with reference numeral 1 for simplicity, constructed in accordance with a second embodiment of the present invention, the heat dissipation module 1 of the second embodiment comprises a uniformly-expanded heat pipe, designated with reference numeral 3′ for distinction, which is different from the uniformly-expanded heat pipe 3 of the first embodiment in that the heat-receiving section 31 of the uniformly-expanded heat pipe 3 of the first embodiment is replaced by a heat-receiving section 31′ that, instead of being comprised of a primitive segment and an expanded segment, is totally comprised of an expanded segment, which comprises a gradually-expanded portion 311′ and a uniformly-expanded portion 312′. The gradually-expanded portion 311′ is connected to the heat-transfer section 32, and the uniformly-expanded portion 312′ is connected to the gradually-expanded portion 311′ and is constructed to have a cross-sectional dimension greater than that of the heat-transfer section 32. The gradually-expanded portion 311′ has a cross-sectional dimension that is increased from the connection thereof with the heat-transfer section 32 toward the connection thereof with the uniformly-expanded portion 312′.

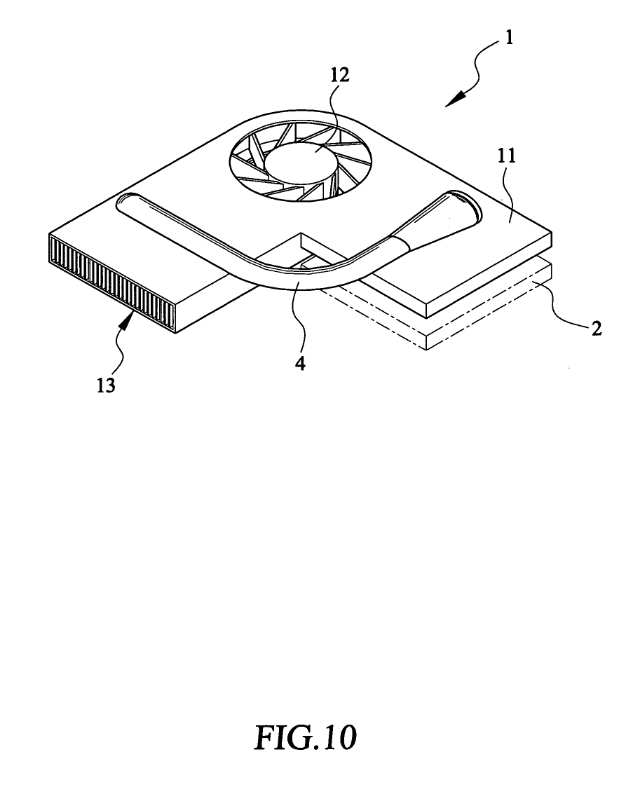

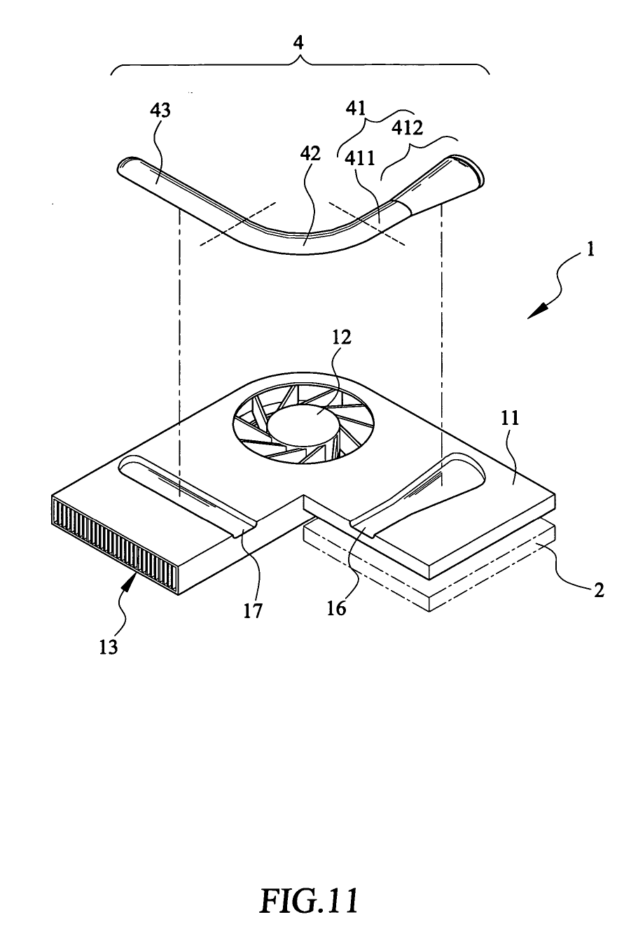

With reference to FIGS. 10 and 11, which show a perspective view and an exploded view of a heat dissipation module, also designated with reference numeral 1 for simplicity, constructed in accordance with a third embodiment of the present invention, the heat dissipation module 1 of the third embodiment comprises a gradually-expanded heat pipe 4 comprising a heat-receiving section 41, a heat-transfer section 42, and a heat-dissipating section 43.

The heat-receiving section 41 is coupled to an end of a heat conduction box 11 of the heat dissipation module 1 that physically contacts a heat source formed by a heat-generating element 2 and the heat-dissipating section 43 is coupled to a heat dissipation fin section 13 of the heat dissipation module 1 whereby heat generated by the heat-generating element 2 is transferred through the heat-transfer section 42 and the heat-dissipating section 43 to heat dissipation fins that constitute the heat dissipation fin module 13, which, together with heat dissipation airflows induced by a fan 12, effectively dissipates heat transferred to the heat dissipation fins to the surroundings.

The instant embodiment is different from the conventional heat pipe in that the heat-receiving section 41 of the gradually-expanded heat pipe 4 of the present invention comprises a primitive segment 411 and an expanded segment 412. The primitive segment 411 is connected to the heat-transfer section 42. The expanded segment 412 is connected to the primitive segment 411. The expanded segment 412 is formed in a gradually-expanded structure having a cross-sectional dimension gradually increased from the connection thereof with the primitive segment 411 toward a free end.

A heat-receiving section receiving slot 16 and a heat-dissipating section receiving slot 17 are formed at suitable locations of the heat conduction box 11 an the heat dissipation fin module 13 respectively. Furthermore, the heat-receiving section 41 and the heat-dissipating section 43 of the gradually-expanded heat pipe 4 are received and retained in the heat-receiving section receiving slot 16 and the heat-dissipating section receiving slot 17 of the heat dissipation module 1, respectively.

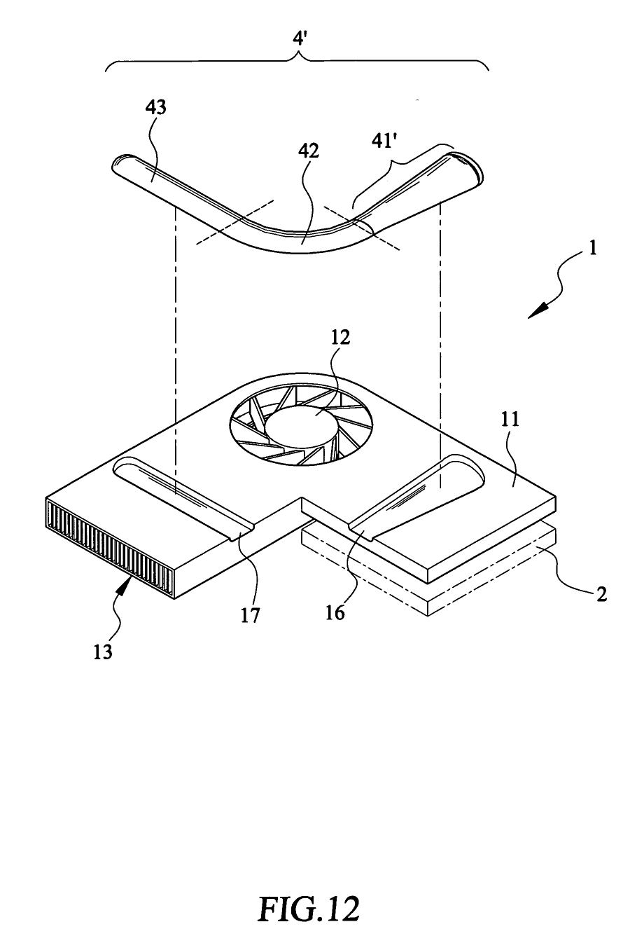

With reference to FIG. 12, which shows an exploded view of a heat dissipation module, also designated with reference numeral 1 for simplicity, constructed in accordance with a fourth embodiment of the present invention, the heat dissipation module 1 of the fourth embodiment comprises a gradually-expanded heat pipe, designated with reference numeral 4′ for distinction, to replace the gradually-expanded heat pipe 4 of the third embodiment. The gradually-expanded heat pipe 4′ of the fourth embodiment is different from the gradually-expanded heat pipe 4 of the third embodiment in that the heat-receiving section 41 of the gradually-expanded heat pipe 4 of the third embodiment is replaced by a heat-receiving section 41′ that has a gradually expanded structure. The gradually-expanded heat-receiving section 41′ has a cross-sectional dimension that is increased from the connection thereof with the heat transfer section 42 toward a free end.

Although the present invention has been described with reference to the preferred embodiment thereof, it is apparent to those skilled in the art that a variety of modifications and changes may be made without departing from the scope of the present invention which is intended to be defined by the appended claims.

What is claimed is:

1. A heat pipe comprising a heat-receiving section, a heat-transfer section, and a heat-dissipating section, wherein the heat-transfer section is connected between the heat-receiving section and the heat-dissipating section in a thermally conductive manner, the heat-receiving section, the heat-transfer section, and the heat-dissipating section each having a first dimension, the heat-receiving section comprising an expanded segment having a first dimension that is greater than the first dimension of the heat-transfer section.

2. The heat pipe as claimed in claim 1, wherein the expanded segment comprises a gradually-expanded portion and a uniformly-expanded portion, the gradually-expanded portion being connected to the heat-transfer section, the uniformly-expanded portion being connected to the gradually-expanded portion, the gradually-expanded portion having a cross-sectional dimension that is gradually increased from the connection thereof with the heat-transfer section toward the connection thereof with the uniformly-expanded portion.

3. The heat pipe as claimed in claim 1, wherein the expanded segment comprises a gradually-expanded structure that has a cross-sectional dimension gradually increased from the connection thereof with the heat-transfer section.

4. The heat pipe as claimed in claim 1, wherein the heat-receiving section, the heat-transfer section, and the heat-dissipating section each have a second dimension, the expanded segment of the heat-receiving section having a second dimension that is greater than the second dimension of the heat-transfer section.

5. A heat pipe comprising a heat-receiving section, a heat-transfer section, and a heat-dissipating section, wherein the heat-transfer section is connected between the heat-receiving section and the heat-dissipating section in a thermally conductive manner, the heat-receiving section, the heat-transfer section, and the heat-dissipating section each having a first dimension, the heat-receiving section comprising an expanded segment having a first dimension that is greater than the first dimension of the heat-dissipating section.

6. The heat pipe as claimed in claim 5, wherein the expanded segment comprises a gradually-expanded portion and a uniformly-expanded portion, the gradually-expanded portion being connected to the heat-transfer section, the uniformly-expanded portion being connected to the gradually-expanded portion, the gradually-expanded portion having a cross-sectional dimension that is gradually increased from the connection thereof with the heat-transfer section toward the connection thereof with the uniformly-expanded portion.

7. The heat pipe as claimed in claim 5, wherein the expanded segment comprises a gradually-expanded structure that has a cross-sectional dimension gradually increased from the connection thereof with the heat-transfer section.

8. The heat pipe as claimed in claim 5, wherein the heat-receiving section, the heat-transfer section, and the heat-dissipating section each have a second dimension, the expanded segment of the heat-receiving section having a second dimension that is greater than the second dimension of the heat-dissipating section.

9. A heat dissipation module comprising a heat conduction box, a heat dissipation fin module, and a heat pipe comprising a heat-receiving section, a heat-transfer section, and a heat-dissipating section, wherein the heat-receiving section and the heat-dissipating section are in physical engagement with the heat conduction box and the heat dissipation fin module respectively, the heat-receiving section, the heat-transfer section, and the heat-dissipating section each having a first dimension, the heat-receiving section of the heat pipe comprising an expanded segment having a first dimension that is greater than the first dimension of the heat-transfer section.

10. The heat dissipation module as claimed in claim 9, wherein the expanded segment comprises a gradually-expanded portion and a uniformly-expanded portion, the gradually-expanded portion being connected to the heat-transfer section, the uniformly-expanded portion being connected to the gradually-expanded portion, the gradually-expanded portion having a cross-sectional dimension that is gradually increased from the connection thereof with the heat-transfer section toward the connection thereof with the uniformly-expanded portion.

11. The heat dissipation module as claimed in claim 9, wherein the expanded segment comprises a gradually-expanded structure that has a cross-sectional dimension gradually increased from the connection thereof with the heat-transfer section.

12. The heat dissipation module as claimed in claim 9, wherein the heat-receiving section, the heat-transfer section, and the heat-dissipating section each have a second dimension, the expanded segment of the heat-receiving section having a second dimension that is greater than the second dimension of the heat-transfer section.

13. The heat dissipation module as claimed in claim 9 further comprising a fan arranged between the heat conduction box and the heat dissipation fin module.

14. A heat dissipation module comprising a heat conduction box, a heat dissipation fin module, and a heat pipe comprising a heat-receiving section, a heat-transfer section, and a heat-dissipating section, wherein the heat-receiving section and the heat-dissipating section are in physical engagement with the heat conduction box and the heat dissipation fin module respectively, the heat-receiving section, the heat-transfer section, and the heat-dissipating section each having a first dimension, the heat-receiving section of the heat pipe comprising an expanded segment having a first dimension that is greater than the first dimension of the heat-dissipating section.

15. The heat dissipation module as claimed in claim 14, wherein the expanded segment comprises a gradually-expanded portion and a uniformly-expanded portion, the gradually-expanded portion being connected to the heat-transfer section, the uniformly-expanded portion being connected to the gradually-expanded portion, the gradually-expanded portion having a cross-sectional dimension that is gradually increased from the connection thereof with the heat-transfer section toward the connection thereof with the uniformly-expanded portion.

16. The heat dissipation module as claimed in claim 14, wherein the expanded segment comprises a gradually-expanded structure that has a cross-sectional dimension gradually increased from the connection thereof with the heat-transfer section.

17. The heat dissipation module as claimed in claim 14, wherein the heat-receiving section, the heat-transfer section, and the heat-dissipating section each have a second dimension, the expanded segment of the heat-receiving section having a second dimension that is greater than the second dimension of the heat-dissipating section.

18. The heat dissipation module as claimed in claim 14 further comprising a fan arranged between the heat conduction box and the heat dissipation fin module.
